(19) United States
(12) Patent Application Publication
(10) Pub. No.: US 2013/0276694 A1
(43) Pub. Date: Oct. 24, 2013

(54) QUARTZ CRUCIBLE FOR GROWING SILICON SINGLE CRYSTAL, METHOD OF MANUFACTURING QUARTZ CRUCIBLE FOR GROWING SILICON SINGLE CRYSTAL AND METHOD OF MANUFACTURING SILICON SINGLE CRYSTAL

(71) Applicant: PANASONIC CORPORATION, Osaka (JP)

(72) Inventors: Hidetoshi UTSURO, Osaka (JP); Masafumi OKAMOTO, Osaka (JP); Ryo KUWABARA, Osaka (JP); Naoya RYOKI, Osaka (JP)

(73) Assignee: PANASONIC CORPORATION, Osaka (JP)

(21) Appl. No.: 13/792,561

(22) Filed: Mar. 11, 2013

(30) Foreign Application Priority Data
Apr. 20, 2012 (JP) JP 2012-096953

(51) Int. Cl. C30B 15/10; C30B 15/14

(52) U.S. Cl. CPC C30B 15/10; C30B 15/14
USPC 117/35; 117/208; 65/33.4

(57) ABSTRACT

A quartz crucible for growing silicon single crystal comprises a crucible body made of a quartz material and a coating layer of a pure silicon which is formed on an inner wall of the crucible body and has purity equivalent to a silicon material that is to be filled into the crucible body. The pure silicon of the coating layer melts together with a silicon material filled in the quartz crucible.

### BACKGROUND OF THE INVENTION

1. Field of the Invention

The present invention relates to a method of manufacturing a silicon single crystal by the Czochralski method, a quartz crucible for growing silicon single crystal used for the manufacture, and a method of manufacturing the quartz crucible for growing silicon single crystal.

2. Related Art of the Invention

Conventionally, the Czochralski process has been used as a method of manufacturing a single crystal silicon ingot which produces a silicon wafer, and the Czochralski process serves as technology completed mostly.

FIG. 8 shows a state when a silicon single crystal is pulled-up in the conventional Czochralski process.

In the Czochralski process, a silicon raw material is filled into a quartz crucible 92, and the quartz crucible 92 is heated by a heater which surrounds the quartz crucible 92 to melt the filled silicon raw material and obtain polycrystalline silicon melt 93.

Next, a seed crystal 94 is pulled up gradually while being rotated with touching a melting surface of the polycrystalline silicon melt 93, and as a result, the crystal grows with a solidification of a contact surface, and a cylindrical silicon single crystal 95 can be obtained.

However, there are following problems in the manufacturing process of the silicon single crystal using the conventional Czochralski method. That is, one of them is that an inner wall of the quartz crucible peels off and the silicon melt is polluted, and the other problem is that a melting step takes a long time because the silicon raw material adheres to the inner wall of the quartz crucible.

These problems are described below.

In the Czochralski process, FIG. 9(A) shows a state when the silicon raw material is filled, and FIG. 9(B) shows a diagram to describe the problems at the time of being filled up with the silicon raw material.

First, as shown in FIG. 9(A), polysilicon lumps 97 as raw material are filled into a quartz crucible 98. At that time, as shown in FIG. 9(B), a minute SiO₂ chipping 99 occurs because the polysilicon lump 97 rubs an inner wall of the quartz crucible 98, and as a result, silicon melt after melting the polysilicon lump 97 is polluted by a quartz fragment.

In a filling step shown in FIG. 9(A), the polysilicon lump 97 is pushed against the inner wall of the quartz crucible 98, and as a result, the polysilicon lump 97 may sink into the inner wall of the quartz crucible 98 as shown in FIG. 9(B) and a sticking 96 may occur. When the polysilicon lump 97 adheres to the inner wall of the quartz crucible 98, the melting step requires a long time.

A quartz crucible of construction in which a film (for example, Si₃N₄), that is insoluble in silicon polycrystal melt, is disposed in the upper part of the inner wall surface is disclosed in Patent Document 1 (Japanese Patent Laid-Open No. S57-71894) in order to make oxygen concentration uniform, which is contained in the silicon single crystal to be manufactured. However, even when the quartz crucible of such construction is used, at the time of filling the silicon raw material, the SiN chipping occurs and pollutes the silicon melt, and/or the silicon raw material sticks to a layer of the insoluble film, and as a result, the same problems as above occur.

In view of the above-described conventional problems, it is an object of the present invention to provide a quartz crucible for growing silicon single crystal, a method of manufacturing the quartz crucible for growing silicon single crystal and a method of manufacturing a silicon single crystal which can prevent contamination and can shorten melting time in the Czochralski process.

### SUMMARY OF THE INVENTION

The 1^{st} aspect of the present invention is a quartz crucible for growing silicon single crystal comprising:

a crucible body made of a quartz material; and

a coating layer of a pure silicon which is formed on an inner wall of the crucible body and has a purity equivalent to a silicon material that is to be filled into the crucible body.

The 2^{nd} aspect of the present invention is the quartz crucible for growing silicon single crystal according to the 1^{st} aspect of the present invention, wherein

the coating layer is a polycrystalline silicon made by a polycrystalline processing.

The 3^{rd} aspect of the present invention is the quartz crucible for growing silicon single crystal according to the 1^{st} aspect of the present invention, wherein

a thickness of the coating layer at a top of the crucible body is thinner than at least a thickness of the coating layer at a bottom of the crucible body.

The 4^{th} aspect of the present invention is the quartz crucible for growing silicon single crystal according to the 1^{st} aspect of the present invention, wherein

an unevenness surface is formed on the coating layer.

The 5^{th} aspect of the present invention is a method of manufacturing a quartz crucible for growing silicon single crystal comprising:

applying a silicon powder to an inner wall of a crucible body made of a quartz material and

forming a coating layer of a pure silicon by changing the applied silicon powder to a polycrystalline silicon by a partial heat treatment.

The 6^{th} aspect of the present invention is the method of manufacturing the quartz crucible for growing silicon single crystal according to the 5^{th} aspect of the present invention, wherein

the coating layer is formed so that a thickness of the coating layer at a top of the crucible body is thinner than at least a thickness of the coating layer at a bottom of the crucible body.

The 7^{th} aspect of the present invention is the method of manufacturing the quartz crucible for growing silicon single crystal according to the 5^{th} aspect of the present invention, comprising:

forming an unevenness surface on the coating layer.

The 8^{th} aspect of the present invention is a method of manufacturing a silicon single crystal comprising:

a filling step of filling a polysilicon lump as raw material into a quartz crucible for growing silicon single crystal, the quartz crucible having a crucible body made of a quartz material upon which a coating layer of a pure silicon is formed on an inner wall thereof, the coating layer having a purity equivalent to a silicon material that is to be filled into the crucible body;

a melting step of heating the quartz crucible for growing silicon single crystal, to melt the filled polysilicon lump; and

a single crystal pulling up step of pulling up a silicon single crystal from silicon melt liquid which is made by melting the polysilicon lump, while heating the quartz crucible for growing silicon single crystal.

The 9^{th} aspect of the present invention is the method of manufacturing the silicon single crystal according to the 8^{th} aspect of the present invention, wherein

the coating layer which is formed on the inner wall of the crucible body of the quartz crucible for growing silicon single crystal, is a polycrystalline silicon made by a polycrystalline processing.

The 10^{th} aspect of the present invention is the method of manufacturing the silicon single crystal according to the 8^{th} aspect of the present invention, wherein

in the melting step, a pure silicon of the coating layer melts.

The 11^{th} aspect of the present invention is the method of manufacturing the silicon single crystal according to the 8^{th} aspect of the present invention, wherein

in the filling step, the polysilicon lump is filled so that it contacts closely with the coating layer which is formed on the inner wall of the crucible body of the quartz crucible for growing silicon single crystal, and

in the melting step, the crucible body is heated with a heater from an outside.

The 12^{th} aspect of the present invention is the method of manufacturing the silicon single crystal according to the 8^{th} aspect of the present invention, wherein

in the filling step, the polysilicon lump is filled with being pushed against the coating layer so that the coating layer which is formed on the inner wall of the crucible body of the quartz crucible for growing silicon single crystal, is transformed or is separated partially, and

in the melting step, a fragment of a pure silicon of the separated coating layer melts together with the polysilicon lump.

The 13^{th} aspect of the present invention is the method of manufacturing the silicon single crystal according to the 8^{th} aspect of the present invention, wherein

after the melting step, the coating layer remains on the inner wall of the crucible body above a surface of the silicon melt liquid.

The 14^{th} aspect of the present invention is the method of manufacturing the silicon single crystal according to the 8^{th} aspect of the present invention, wherein

a scrap silicon of a single crystal, which comes out as a kerf loss in a silicon wafer manufacturing step which is a step after a silicon ingot manufacture, is used as the pure silicon of the coating layer formed on the inner wall of the crucible body of the quartz crucible for growing silicon single crystal.

The present invention can provide a quartz crucible for growing silicon single crystal, a method of manufacturing the quartz crucible for growing silicon single crystal and a method of manufacturing a silicon single crystal which can prevent contamination and can shorten melting time in the Czochralski process.

### BRIEF DESCRIPTION OF THE DRAWINGS

FIG. 1(A) is a sectional view of a quartz crucible according to a first embodiment of the present invention;

FIG. 1(B) is a sectional view of the quartz crucible at the time of a filling step of a silicon material in a single crystal silicon ingot manufacturing, according to the first embodiment of the present invention;

FIG. 1(C) is a sectional view of the quartz crucible after a melting step of the silicon material in the single crystal silicon ingot manufacturing, according to the first embodiment of the present invention;

FIG. 2 is a diagram to describe that conventional problems are solvable by using the quartz crucible according to the first embodiment of the present invention;

FIG. 3 is a sectional view of the quartz crucible having a construction in which thickness of Si coating layer differs in an upper part and a lower part according to the first embodiment of the present invention;

FIG. 4(A) is a diagram to describe a forming method of an Si coating layer on a quartz crucible according to a second embodiment of the present invention;

FIG. 4(B) is a sectional view of the quartz crucible in which the Si coating layer has been formed according to the second embodiment of the present invention;

FIG. 5(A) is a diagram to describe another forming method of the Si coating layer on the quartz crucible according to the second embodiment of the present invention;

FIG. 5(B) is a sectional view of the quartz crucible in which an Si coating layer having an unevenness surface has been formed according to the second embodiment of the present invention;

FIG. 6 is a diagram to describe a shield effect of radiant heat rays in a single crystal pulling up step at a quartz crucible according to a third embodiment of the present invention;

FIG. 7 is a sectional view of the quartz crucible having a construction in which an insoluble film is formed thereon according to the third embodiment of the present invention;

FIG. 8 is a diagram showing a state when a silicon single crystal is pulled-up in a conventional Czochralski process;

FIG. 9(A) is a diagram showing a state when a silicon raw material is filled in the conventional Czochralski process; and

FIG. 9(B) is a diagram to describe a problem at the time of being filled up with the silicon raw material in the conventional Czochralski process.

### DESCRIPTION OF SYMBOLS

12, 31, 41, 51, 71, 81 Crucible body unit
14 Polysilicon lump
13, 72 Polycrystalline silicon melt
17, 83 Si coating layer
18 Pure Si chipping
32 Surface position of silicon melt
33 Thick film Si coating layer
34 Thin film Si coating layer
42, 52 Silicon powder
43, 53 Atmospheric pressure plasma torch
44, 54 Local heating
45 Polycrystalline Si coating layer
55 Control device
56 Modulation of the heating intensity
57 Polycrystalline Si unevenness coating layer
73 Silicon ingot
75 Si coating layer residual part
76 Radiant heat ray
82 Insoluble film
92, 98 Quartz crucible
93 Polycrystalline silicon melt
94 Seed crystal
95 Silicon single crystal
96 Sticking
97 Polysilicon lump
99 SiO₂ chipping

### PREFERRED EMBODIMENTS OF THE INVENTION

Hereinafter, embodiments of the present invention are described with reference to the drawings.

### First Embodiment

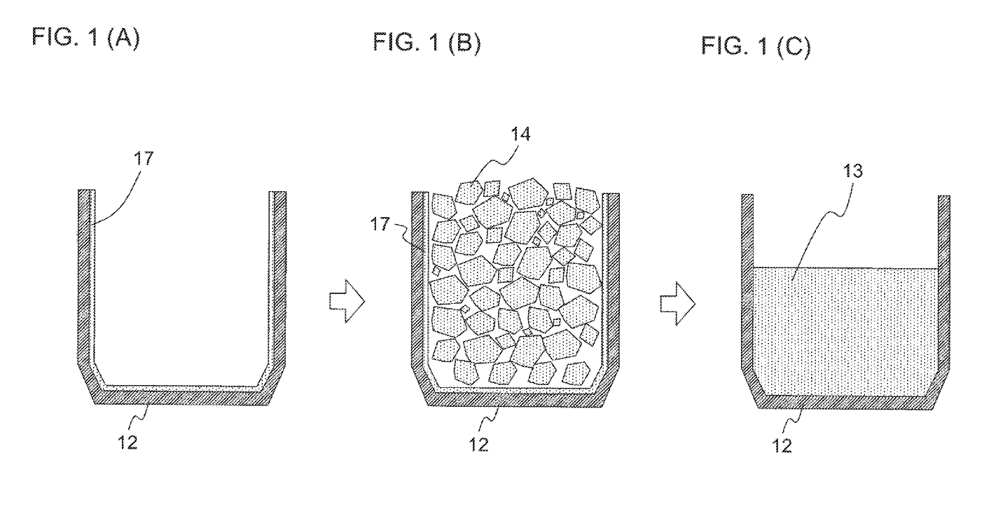

FIG. 1(A) shows a sectional view of a quartz crucible according to a first embodiment of the present invention.

FIG. 1(B) shows a sectional view of the quartz crucible at the time of a filling step of a silicon material in a single crystal silicon ingot manufacturing. FIG. 1(C) is a sectional view of the quartz crucible after a melting step of the silicon material in the single crystal silicon ingot manufacturing.

As shown in FIG. 1(A), an inner wall of a crucible body unit 12 of the quartz crucible of the first embodiment is coated by a pure silicon which has purity equivalent to a polysilicon lump 14 to be filled to the quartz crucible, and as a result, an Si coating layer 17 is formed on the inner wall of the crucible body unit 12. The crucible body unit 12 is a generally used quartz crucible for growing silicon single crystal, which is made from quartz. The quartz crucible of the first embodiment is provided with construction in which the Si coating layer 17 is formed on the inner wall of the generally used quartz crucible.

In the manufacturing process of the single crystal silicon ingot, first, as shown in FIG. 1(B), the polysilicon lump 14 is filled into the quartz crucible of the first embodiment.

Next, the melting step is performed. At the time of the end of the melting step, as shown in FIG. 1(C), both the polysilicon lump 14 and the Si coating layer 17 are melted, and polycrystalline silicon melt 13 is obtained.

In the above, in the first embodiment, the Si coating layer 17 itself is melted in the melting step.

The crucible body unit 12 corresponds to an example of a crucible body according to the present invention. The Si coating layer 17 corresponds to an example of a coating layer according to the present invention. The polysilicon lump 14 corresponds to an example of a silicon material according to the present invention.

Next, by using the quartz crucible of the first embodiment, the reason which can solve the above-mentioned conventional problems is described below.

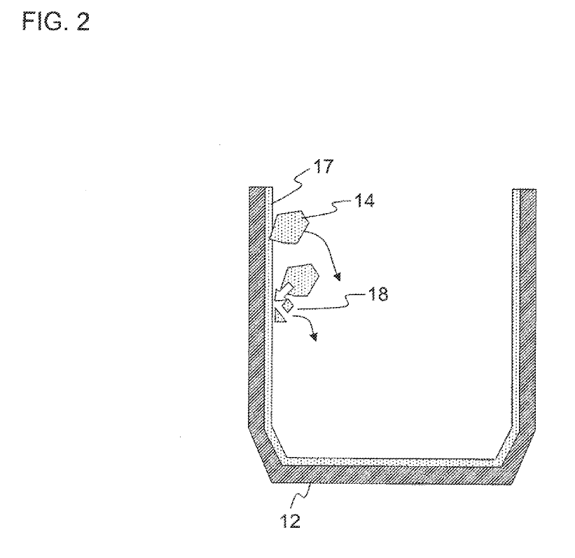

FIG. 2 shows a diagram to describe that the conventional problems are solvable by using the quartz crucible of the first embodiment.

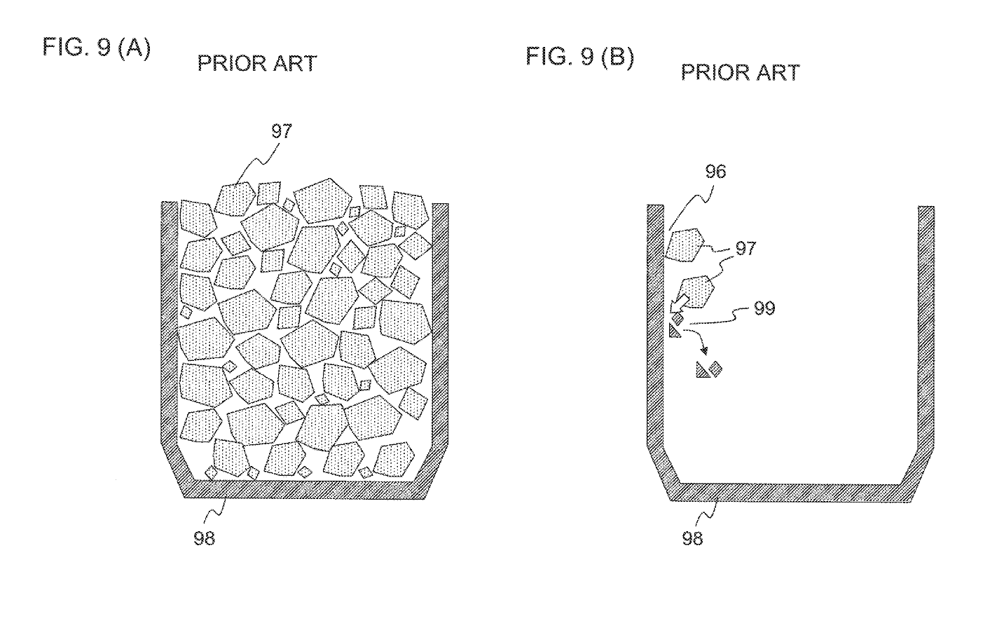

Because the Si coating layer 17 is formed on the inner wall of the crucible body unit 12, the polysilicon lump 14 does not contact a surface of the crucible body unit 12 directly when the polysilicon lump 14 as raw material is filled into the quartz crucible. Therefore, it is avoidable that the quartz fragment as described in FIG. 9(B) goes into the inside of the quartz crucible, and mixes in the polycrystalline silicon melt 13 as a contamination.

A chipping occurs when the polysilicon lump 14 is filled. However, even if the Si coating layer 17 is chipped, a contamination does not occur because what is mixed is a pure Si chipping 18 with purity equivalent to the polysilicon lump 14.

Because the Si coating layer 17 is the pure silicon with purity equivalent to the polysilicon lump 14 as raw material, a melting point of the Si coating layer 17 is same as a melting point of the polysilicon lump 14 as raw material. Therefore, the Si coating layer 17 itself is also melted when the polysilicon lump 14 is melted, the polysilicon lump 14 which sinks into the Si coating layer 17 falls according to the melting of the Si coating layer 17, then it does not become a sticking. In the above, the sticking 96 as described in FIG. 9(B), in which the polysilicon lump 97 sticks to the inner wall of the quartz crucible 98, can be prevented.

By using the quartz crucible of the construction described in the first embodiment, a prevention of contamination and a shortening of melting time can be realized by the melting step having an effect of no chipping and no sticking.

In the method of manufacturing the silicon single crystal of the first embodiment, the polysilicon lump 14 as raw material is filled into the inside of the crucible body unit 12 so that the contact area between the polysilicon lump 14 and the Si coating layer 17 can be stuck largely. Thereby, at the melting step of heating by a heater from the outside of the crucible body unit 12, a heat transfer from the crucible body unit 12 to the polysilicon lump 14 can be improved.

The polysilicon lump 14 as raw material can be filled into the crucible body unit 12 while pushing the polysilicon lump 14 to the Si coating layer 17 so that the Si coating layer 17 is transformed or is separated partially. Thereby, a fragment of the separated Si coating layer 17 is melted together with the polysilicon lump 14, and the heat transfer in the melting step can be improved.

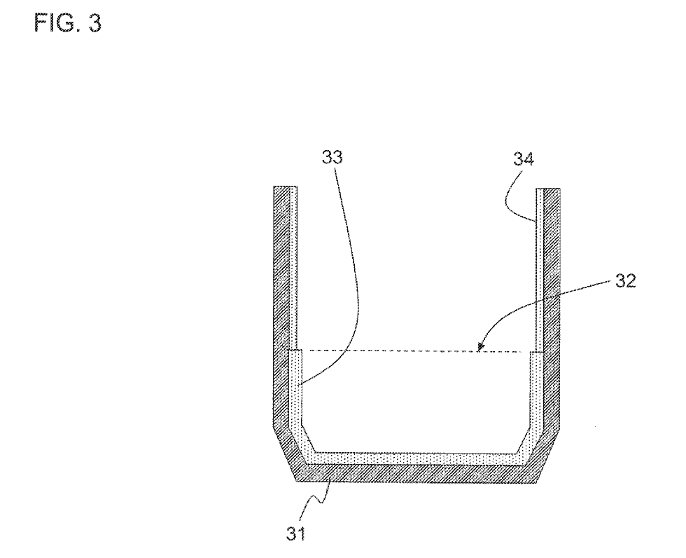

FIG. 3 shows a sectional view of a quartz crucible of another construction of the first embodiment. The quartz crucible shown in FIG. 3 has a construction in which a thickness of the Si coating layer differs in an upper part and a lower part.

A surface position of silicon melt 32 shown in FIG. 3 with a dashed line shows a position of a surface of the silicon melt after melting of the polysilicon lump as raw material which has been filled into the inside of the quartz crucible.

In the quartz crucible shown in FIG. 3, in order to prevent the polysilicon lump from adhering to a crucible body unit 31 and the melting time from increasing, an Si coating layer formed on an inner wall surface of the crucible body unit 31 has the following construction. A thick film Si coating layer 33 is arranged at the lower position than the surface position of silicon melt 32. A thin film Si coating layer 34 having a thickness which is thinner than a thickness of the thick film Si coating layer 33 is arranged at the higher position than the surface position of silicon melt 32.

The thickness of the thin film Si coating layer 34 is set up so that a heat capacity of the thin film Si coating layer 34 may become smaller enough than a heat capacity of a material of the crucible body unit 31, and as a result, a rise in heat of the thin film Si coating layer 34 can follow enough a rise in heat of the crucible body unit 31. The thickness of the thin film Si coating layer 34 shall be around 1 mm which is the 1/10 to the thickness of the material of the crucible body unit 31 being around 10 mm. The thickness of the thick film Si coating layer 33 shall be several millimeters which is several times the thickness of the thin film Si coating layer 34.

Thereby, a contact area between the thin film Si coating layer 34 above the surface position of silicon melt 32 and the crucible body unit 31 does not change, but the volume of the thin film Si coating layer 34 becomes small and the heat capacity of the thin film Si coating layer 34 becomes small. Therefore, when a heater which surrounds the quartz crucible heats the quartz crucible and the filled polysilicon lump is melted, the temperature of whole of the thin film Si coating layer 34 rises quickly due to a heat transfer from the crucible body unit 31 and the thin film Si coating layer 34 is melted. That is, the thin film Si coating layer 34 becomes a silicon coating which melts easily at the time of the melting of the polysilicon lump as raw material.

As a result, more efficiently, the conventional sticking phenomenon can be prevented.

The construction of the quartz crucible as shown in FIG. 3 corresponds to an example of a composition that a thickness of the coating layer at a top of the crucible body is thinner than a thickness of the coating layer at a bottom of the crucible body according to the present invention. The thickness of the thin film Si coating layer 34 corresponds to an example of the thickness of the coating layer at the top of the crucible body according to the present invention. The thickness of the thick film Si coating layer 33 corresponds to an example of the thickness of the coating layer at the bottom of the crucible body according to the present invention.

In FIG. 3, the thin film Si coating layer 34 is arranged above the surface position of silicon melt 32 and the thick film Si coating layer 33 is arranged below the surface position of silicon melt 32. The boundary portion between the thin film Si coating layer 34 and the thick film Si coating layer 33 can be located lower position than the surface position of silicon melt 32. That is, the lower part of the thin film Si coating layer 34 can reach to the lower position than the surface position of silicon melt 32.

In FIG. 3, the thickness of the Si coating layer formed on the inner wall surface of the crucible body unit 31 is two kinds of thickness which are a thickness of the thin film Si coating layer 34 and a thickness of the thick film Si coating layer 33. The Si coating layer having three or more kinds of thickness can be arranged so that it thickens from the upper part to the under part of the crucible body unit 31. It is not limited to the construction as shown in FIG. 3 in which the Si coating layer having different thickness is arranged in the shape of stairs at the upper part and the under part of the crucible body unit 31. The Si coating layer can be arranged so that the thickness is changing continuously from the upper part to the under part of the crucible body unit 31.

### Second Embodiment

A forming method of the Si coating layer on the quartz crucible of the present invention is described in a second embodiment of the present invention.

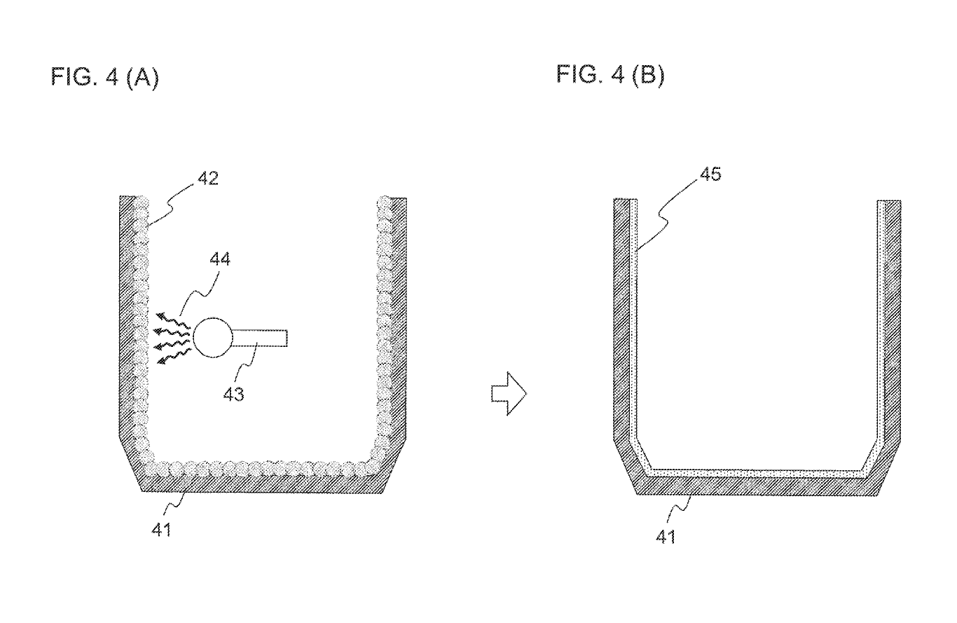

FIG. 4(A) shows a diagram to describe the forming method of the Si coating layer on the quartz crucible of the second embodiment. FIG. 4(B) shows a sectional view of the quartz crucible after the Si coating layer has been formed.

In the second embodiment, when an inner wall of a crucible body unit 41 made from quartz is coated by the pure silicon, a poly-crystallize processing is carried out as shown in FIG. 4(A).

Here, a silicon powder 42 is applied to the inner wall of the crucible body unit 41, a local heating 44 is performed by using an atmospheric pressure plasma torch 43.

As the atmospheric pressure plasma torch 43 used here, for example, an apparatus can be used, which discharges a plasma torch generated at the tip of a quartz pipe by preparing a coil of several turns in a quartz multiplex pipe and supplying an electric power through a matching circuit. Since temperature rises locally only in the portion by which plasma is generated and in its neighborhood, the applied silicon powder 42 can be poly-crystallized with suppressing a transformation of the crucible body unit 41 by the rise in heat. Specifically, since a distance between the tip of the quartz pipe and the applied silicon powder 42 is kept at about 5 mm or more and 10 mm or less, only the temperature of the applied silicon powder 42 is raised, and a polycrystalline Si coating layer 45 can be formed as shown in FIG. 4(B).

By changing to the polycrystalline silicon, a composition becomes dense and a thermal conductivity improves markedly compared with the silicon powder 42. Since the polycrystalline Si coating layer 45 melts easily at the time of melting, the sticking phenomenon can be prevented more certainly.

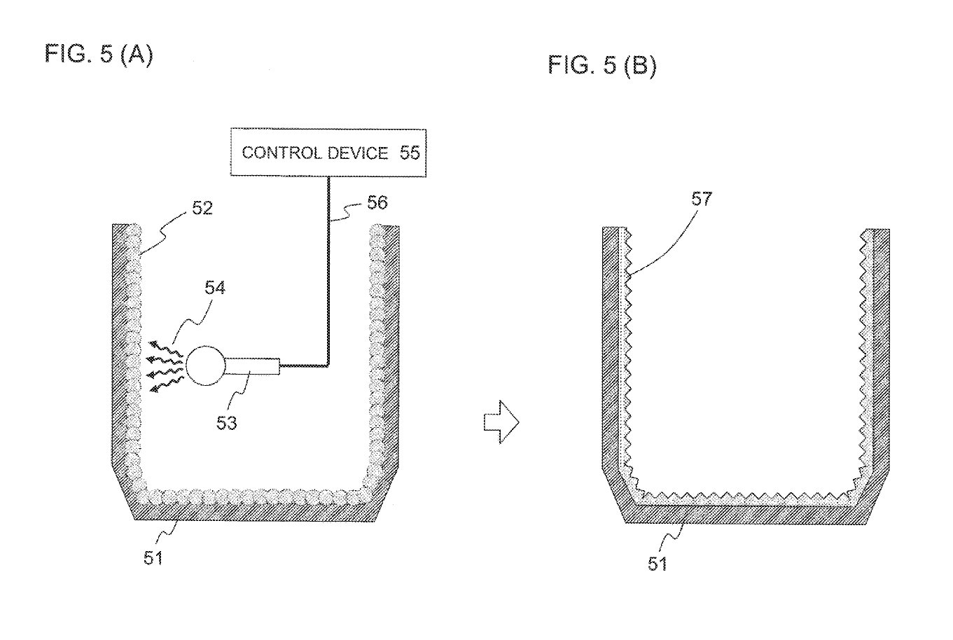

FIG. 5(A) shows a diagram to describe another forming method of the Si coating layer on the quartz crucible of the second embodiment. FIG. 5(B) shows a sectional view of the quartz crucible after the Si coating layer has been formed by using the forming method shown in FIG. 5(A).

In the forming method shown in FIG. 5(A), when a local heating 54 is performed after a silicon powder 52 is applied to an inner wall of a crucible body unit 51, an intensity of the local heating 54 is modulated by applying a modulation of the heating intensity 56 to an atmospheric pressure plasma torch 53 by using control device 55, and a polycrystalline Si unevenness coating layer 57 having an unevenness surface shown in FIG. 5(B) is formed.

Specifically, an intensity of plasma is modulated by controlling an electric power supplied to the atmospheric pressure plasma torch 53. Here, when an interval between a convex part and a concave part which are formed is assumed by T(mm) and a scanning rate of the atmospheric pressure plasma torch 53 against the inner wall surface of the crucible body unit 51 is assumed by V(mm/s), and a control is performed so that a time interval between the maximum of electric power and the minimum of electric power becomes to T/V(s).

When the surface of the Si coating layer is the unevenness surface, a contact area between the polysilicon as raw material filled into the quartz crucible and the polycrystalline Si unevenness coating layer 57 can be stuck largely. As a result, at the melting step of heating by the heater from the outside of the quartz crucible, a heat transfer from the crucible body unit 51 to the polysilicon lump can be improved and the high efficiency of the melting step can be realized.

### Third Embodiment

Next, a construction of a quartz crucible of a third embodiment of the present invention is described.

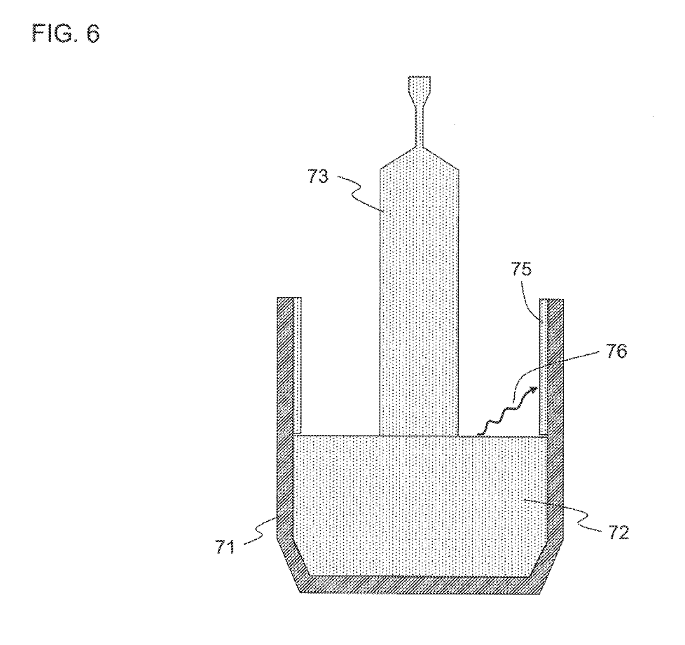

FIG. 6 shows a sectional view to describe a shield effect of radiant heat rays in a single crystal pulling up step at the quartz crucible of the third embodiment.

In the third embodiment, in the melting step in which the raw material that is filled in the quartz crucible is melted, an Si coating layer residual part 75 is retained as shown in FIG. 6 after the melting step instead of melting all of the Si coating layer formed on an inner wall of a crucible body unit 71.

As shown in FIG. 6, since the Si coating layer residual part 75 exists on an area of the quartz crucible above the surface of the silicon melt after the melting step, an effect which shields a radiant heat rays 76 from a polycrystalline silicon melt 72 can be acquired. A transformation due to the heat of the upper part of the crucible body unit 71 can be suppressed by this shield effect.

In this way, when a silicon ingot 73 is pulled up gradually while being rotated with touching the surface of the silicon melt, the crystal grows with a solidification of a contact surface, and a cylindrical silicon single crystal can be obtained while suppressing the transformation of the crucible body unit 71.

In order to make oxygen concentration uniform, which is contained in the silicon single crystal to be manufactured, a film such as Si₃N₄ which is insoluble in silicon polycrystal melt can be formed on the inner wall surface of the crucible body unit, and an Si coating layer can be formed on the insoluble film.

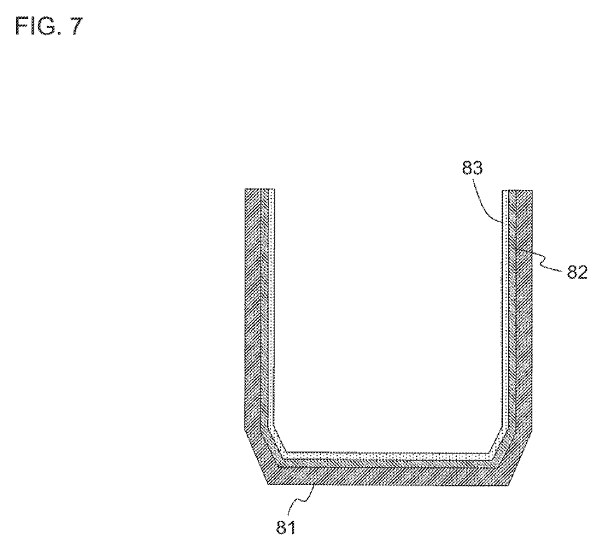

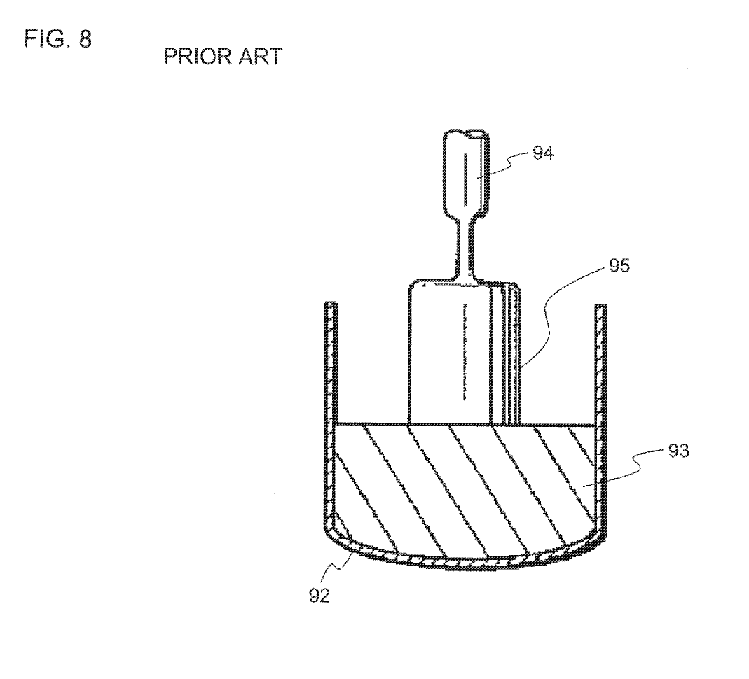

FIG. 7 shows a sectional view of the quartz crucible in which the insoluble film is formed on the inner wall side of the crucible body unit and the Si coating layer is formed on the insoluble film.

Regarding the quartz crucible shown in FIG. 7, the crucible body unit 81 does not contact the silicon polycrystal melt due to the insoluble film 82. Therefore, the crucible body unit 81 does not elute oxygen into the silicon polycrystal melt, the oxygen concentration in the silicon polycrystal melt does not change, and as a result, the oxygen concentration contained in the silicon single crystal to be produced becomes uniform.

When the polysilicon lump as raw material is filled into the quartz crucible, the polysilicon lump does not contact the insoluble film 82 directly due to the existence of the Si coating layer 83. Therefore, a fragment of SiN of the insoluble film 82 is prevented from going into the inside of the quartz crucible and mixing in the silicon melt as a contamination.

In FIG. 7, the insoluble film 82 is formed on whole of the inner wall surface of the crucible body unit 81. The insoluble film 82 can be formed only on the side portion of the inner wall of the crucible body unit 81, which contacts a liquid surface portion of the silicon polycrystal melt in the single crystal pulling up step, except for the bottom portion of the inner wall of the crucible body unit 81.

A scrap silicon occurs in a silicon wafer manufacturing process after a silicon ingot manufacturing process. When the scrap silicon is recycled and is used as the silicon to form the coating layer in the above described each embodiment, an increase in efficiency of a whole process can be attained. A scrap silicon, which occurs as a kerf loss when prismatic silicon is cut out from a columnar silicon ingot or when a prismatic silicon is sliced to generate a silicon wafer, can be used as the scrap silicon which occurs in the silicon wafer manufacturing process.

As described above, by using the quartz crucible for growing silicon single crystal of the present invention, the polysilicon lump as raw material does not contact the surface of the quartz crucible or the insoluble film directly when the polysilicon lump as raw material is filled into the quartz crucible. Therefore, it is avoidable that the quartz fragment or the fragment of SiN goes into the inside of the quartz crucible, and mixes in the silicon melt as the contamination.

By using the quartz crucible for growing silicon single crystal of the present invention, even if the chipping occurs when the polysilicon lump is filled, the contamination dose not generated because the chipping is the pure Si chipping with purity equivalent to the polysilicon lump. Since the Si coating layer itself is also melted when the polysilicon lump is melted, the sticking phenomenon in which the polysilicon lump sticks to the inner wall of the quartz crucible can be prevented. As a result, the prevention of contamination and the shortening of melting time can be realized by the melting step having the effect of no chipping and no sticking.

Thereby, a shortening of a cycle time and an improvement of the length yield when the silicon ingot is pulled up are achieved and the productivity of silicon ingot manufacturing improves. As a result, it becomes possible to manufacture the silicon wafer at low cost.

The quartz crucible for growing silicon single crystal, the method of manufacturing the quartz crucible for growing silicon single crystal and the method of manufacturing the silicon single crystal according to the present invention have effects which can realize the prevention of contamination and the shortening of melting time in the Czochralski process, and are useful as a silicon ingot manufacturing step or the like to manufacture a silicon wafer used for a solar cell or the like.

What is claimed is:

1. A quartz crucible for growing silicon single crystal comprising:
a crucible body made of a quartz material; and
a coating layer of a pure silicon which is formed on an inner wall of the crucible body and has a purity equivalent to a silicon material that is to be filled into the crucible body.

2. The quartz crucible for growing silicon single crystal according to claim 1, wherein
the coating layer is a polycrystalline silicon made by a polycrystalline processing.

3. The quartz crucible for growing silicon single crystal according to claim 1, wherein
a thickness of the coating layer at a top of the crucible body is thinner than at least a thickness of the coating layer at a bottom of the crucible body.

4. The quartz crucible for growing silicon single crystal according to claim 1, wherein
an unevenness surface is formed on the coating layer.

5. A method of manufacturing a quartz crucible for growing silicon single crystal comprising:
applying a silicon powder to an inner wall of a crucible body made of a quartz material and
forming a coating layer of a pure silicon by changing the applied silicon powder to a polycrystalline silicon by a partial heat treatment.

6. The method of manufacturing the quartz crucible for growing silicon single crystal according to claim 5, wherein
the coating layer is formed so that a thickness of the coating layer at a top of the crucible body is thinner than at least a thickness of the coating layer at a bottom of the crucible body.

7. The method of manufacturing the quartz crucible for growing silicon single crystal according to claim 5, comprising:
forming an unevenness surface on the coating layer.

8. A method of manufacturing a silicon single crystal comprising:
a filling step of filling a polysilicon lump as a raw material into a quartz crucible for growing silicon single crystal, the quartz crucible having a crucible body made of a quartz material upon which a coating layer of a pure silicon is formed on an inner wall thereof, the coating layer having a purity equivalent to a silicon material that is to be filled into the crucible body;
a melting step of heating the quartz crucible for growing silicon single crystal, to melt the filled polysilicon lump; and
a single crystal pulling up step of pulling up a silicon single crystal from silicon melt liquid which is made by melting the polysilicon lump, while heating the quartz crucible for growing silicon single crystal.

9. The method of manufacturing the silicon single crystal according to claim 8, wherein
the coating layer which is formed on the inner wall of the crucible body of the quartz crucible for growing silicon single crystal, is a polycrystalline silicon made by a polycrystalline processing.

10. The method of manufacturing the silicon single crystal according to claim 8, wherein
in the melting step, a pure silicon of the coating layer melts.

11. The method of manufacturing the silicon single crystal according to claim 8, wherein
in the filling step, the polysilicon lump is filled so that it contacts closely with the coating layer which is formed on the inner wall of the crucible body of the quartz crucible for growing silicon single crystal, and
in the melting step, the crucible body is heated with a heater from an outside.

12. The method of manufacturing the silicon single crystal according to claim 8, wherein
in the filling step, the polysilicon lump is filled with being pushed against the coating layer so that the coating layer which is formed on the inner wall of the crucible body of the quartz crucible for growing silicon single crystal, is transformed or is separated partially, and
in the melting step, a fragment of a pure silicon of the separated coating layer melts together with the polysilicon lump.

13. The method of manufacturing the silicon single crystal according to claim 8, wherein
after the melting step, the coating layer remains on the inner wall of the crucible body above a surface of the silicon melt liquid.

14. The method of manufacturing the silicon single crystal according to claim 8, wherein
a scrap silicon of a single crystal, which comes out as a kerf loss in a silicon wafer manufacturing step which is a step after a silicon ingot manufacture, is used as the pure silicon of the coating layer formed on the inner wall of the crucible body of the quartz crucible for growing silicon single crystal.
